(19) United States
(12) Patent Application Publication
(10) Pub. No.: US 2023/0268448 A1
(43) Pub. Date: Aug. 24, 2023

(54) Fast-Turn-On Floating Island Device and Method for Manufacturing Thereof

(71) Applicant: ZHEJIANG UNIVERSITY, Hangzhou (CN)

(72) Inventors: Kuang SHENG, Hangzhou (CN); Ce WANG, Hangzhou (CN); Hengyu WANG, Hangzhou (CN); Na REN, Hangzhou (CN)

(21) Appl. No.: 18/091,435

(22) Filed: Dec. 30, 2022

(30) Foreign Application Priority Data
Feb. 22, 2022 (CN) 202210162096.6

(51) Int. Cl. H01L 29/872; H01L 29/739; H01L 29/78; H01L 29/861; H01L 29/66

(52) U.S. Cl. CPC H01L 29/872; H01L 29/7397; H01L 29/7813; H01L 29/8613; H01L 29/66143

(57) ABSTRACT

A fast-turn-on floating island device and a method for manufacturing thereof in the field of semiconductor technology. The device comprises a surface layer, a bottom layer and a drift layer which is located between the surface layer and the bottom layer, wherein, the drift layer comprises a plurality of epitaxial layers and a plurality of floating island layers, one of the floating island layers formed between adjacent two of the epitaxial layers, or one of the epitaxial layers between adjacent two of the floating island layers, a first doped region and a second doped region form in at least one of the floating island layers.

### CROSS-REFERENCE TO RELATED APPLICATIONS

The present disclosure claims the priority of Chinese Patent Application No. 202210162096.6, filed to the China. National Intellectual Property Administration on Apr. 7, 2022, which is incorporated herein its entirety by reference.

### TECHNICAL FIELD

The present disclosure generally relates to semiconductor devices, and more particularly but not exclusively relates to a fast-turn-on floating island device and a method for manufacturing thereof.

### BACKGROUND

In recent years, more and more attention has been paid to energy saving and emission reduction worldwide, which puts forward higher requirements for loss control and efficiency improvement of large power electronic devices. Semiconductor power devices, as an important component of power electronic devices, have received wide attention in the industry.

Breakdown voltage is an important indicator of semiconductor power devices, indicating the maximum voltage that the device can withstand. Floating island devices (or floating junction devices) are special power devices, in whose drift layers there are regions that are not directly connected to the electrodes and doped oppositely to the drift layers. At the moment when the floating island device with N-type drift layer switches from blocking state to conducting state, the hole carriers cannot enter the P-type doped region because the P-type doped region inside the drift layer is not directly connected with the electrodes, resulting in negative charges remaining in the P-type doped region. A large number of positive charges are absorbed into the N-type drift layer, which occupies the drift layer in the form of space charges, causing the band bending, thus impeding the electron carrier flow. That is, floating island devices with floating doped region in the drift layer cannot complete conduction recovery at low voltage. In this case, the charge can only conduct through the drift layer if the bias voltage is large enough. When the device is forced turning on, there will be large voltage pulse or hysteresis across the device, thus increasing the switching power loss.

FIG. 1 schematically shows a cross-sectional view of a conventional floating island Schottky diode, comprising a surface layer 1, a bottom layer 2 and a drift layer 19. The surface layer comprises an anode metal 8, and the bottom layer 2 comprises a cathode-drain metal 17. The drift layer 19 is located between the surface layer 1 and the bottom layer 2, comprising a plurality of epitaxial layers 3 and a plurality of floating island layers 7. There is a floating island layer 7 between each adjacent two epitaxial layers 3, or there is an epitaxial layer 3 between each adjacent two floating island layers 7 (refer to FIG. 27). The floating island layers 7 and the epitaxial layers 3 are arranged in the way of staggering upward. The floating island layer 7 comprises the first doped region 4 and the third doped region 6, wherein the doping type of the first doped region 4 is opposite to that of the epitaxial layer 3, and the doping type of the third doped region 5 is the same as that of the epitaxial layer 3. The doping concentration of the third doped region 6 may be equal to or higher than or lower than the doping concentration of the epitaxial layer 3.

Compared to conventional Schottky diode without floating island, the conventional floating island Schottky diode has higher breakdown voltage for the same on-state resistance, or has lower on-state resistance for the same breakdown voltage, so as to reduce on-state power loss. However, at the moment when the floating island Schottky diode switches from blocking state to conducting state, the carriers cannot enter the first doped region 4 because the first doped region 4 inside the drift layer 19 is not directly connected with the electrodes, causing the charges to remain in the first doped region 4. A large number of opposite charges are absorbed into the epitaxial layer 3, which occupies the epitaxial layer 3 in the form of space charges, causing the band bending, thus impeding the carrier flow. That is, floating island Schottky diode cannot complete conduction recovery at low voltage. When the Schottky diode is forced turning on, there will be large voltage pulse or hysteresis across the device, thus increasing the switching power loss.

FIG. 2 schematically shows a cross-sectional view of a conventional floating island MOSFET, comprising a surface layer 1, a bottom layer 2 and a drift layer 19. The surface layer comprises a source metal 11, a channel well doped region 12, a source doped region 13, a gate oxide layer 14, a gate metal and a trench filler 16, and the bottom layer 2 comprises a cathode-drain metal 17. The drift layer 19 is located between the surface layer 1 and the bottom layer 2, comprising a plurality of epitaxial layers 3 and a plurality of floating island layers 7. There is a floating island layer 7 between each adjacent two epitaxial layers 3, or there is an epitaxial layer 3 between each adjacent two floating island layers 7 (refer to FIG. 27). The floating island layers 7 and the epitaxial layers 3 are arranged in the way of staggering upward. The floating island layer 7 comprises the first doped region 4 and the third doped region 6, wherein the doping type of the first doped region 4 is opposite to that of the epitaxial layer 3, and the doping type of the third doped region 5 is the same as that of the epitaxial layer 3. The doping concentration of the third doped region 6 may be equal to or higher than or lower than the doping concentration of the epitaxial layer 3.

Compared to conventional MOSFET without floating island, the conventional floating island MOSFET has higher breakdown voltage for the same on-state resistance, or has lower on-state resistance for the same breakdown voltage, so as to reduce on-state power loss. However, at the moment when the floating island Schottky diode switches from blocking state to conducting state, the carriers cannot enter the first doped region 4 because the first doped region 4 inside the drift layer 19 is not directly connected with the electrodes, causing the charges to remain in the first doped region 4. A large number of opposite charges are absorbed into the epitaxial layer 3, which occupies the epitaxial layer 3 in the form of space charges, causing the band bending, thus impeding the carrier flow. That is, floating island Schottky diode cannot complete conduction recovery at low voltage. When the MOSFET is forced turning on, there will be large voltage pulse or hysteresis across the device, thus increasing the switching power loss.

### SUMMARY

It is an object of the present disclosure to provide a fast-turn-on floating island device and a method for manufacturing thereof.

One embodiment of the present disclosure is directed to a fast-turn-on floating island device, the device includes: a surface layer; a bottom layer; and a drift layer that is located between the surface layer and the bottom layer. The drift layer includes a plurality of epitaxial layers and a plurality of floating island layers, one of the floating island layers forms between each adjacent two of the epitaxial layers, or one of the epitaxial layers forms between each adjacent two of the floating island layers, a first doped region and a second doped region form in at least one of the floating island layers, a doping type of the first doped region is opposite to a doping type of the epitaxial layer, and a doping type of the second doped region is the same as the doping type of the epitaxial layer.

In at least one alternative embodiment, the second doped region is distributed in the first doped region, or part of the second doped region is distributed in the first doped region.

In at least one alternative embodiment, a lower edge of the second doped region is not lower than a lower edge of the first doped region described above, and an upper edge of the second doped region directly contacts the epitaxial layer.

In at least one alternative embodiment, a length of the portion of a second doped region that is distributed in the first doped region is less than a length of the first doped region.

In at least one alternative embodiment, the floating island layer includes a plurality of the second doped regions arranged at intervals.

In at least one alternative embodiment, a total length of the second doped region arranged at intervals is less than a length of the first doped region.

In at least one alternative embodiment, at least one of the include floating island layers further includes a third doped region, and a doping type of the third doped region is the same as the doping type of the epitaxial layer.

In at least one alternative embodiment, when the fast-turn-on floating island device is a fast-turn-on floating-island Schottky diode, the surface layer includes an anode metal, and the bottom layer includes a cathode-drain metal; when the fast-turn-on floating island device is a fast-turn-on floating island PN diode, the surface layer includes an anode metal and an anode doped region, a doping type of the anode doped region is opposite to a doping type of the epitaxial layer, and the bottom layer includes a cathode-drain metal; and when the fast-turn-on floating island device is a fast-turn-on floating island junction barrier Schottky diode, the surface layer includes an anode metal, an anode doped region and an anode epitaxial layer, and a doping type of the anode doped region is opposite to the doping type of the epitaxial layer, and the doping type of the anode epitaxial layer is the same as the doping type of the epitaxial layer, and the bottom layer includes a cathode-drain metal.

In at least one alternative embodiment, when the fast-turn-on floating island device is the fast-turn-on floating island junction barrier Schottky diode, the surface layer further includes the second doped region.

In at least one alternative embodiment, when the fast-turn-on floating island device is a fast-turn-on floating island MOSFET, the surface layer includes a source metal, a channel well doped region, a source doped region, a gate oxide layer, a gate metal, and the bottom layer includes a cathode-drain metal; when the fast-turn-on floating island device is a fast-turn-on floating island IGBT, the surface layer includes a source metal, a channel well doped region, a source doped region, a gate oxide layer, a gate metal, and the bottom layer includes a cathode-drain metal and a drain doped region.

In at least one alternative embodiment, the drift layer includes two or more floating island layers, and the structures of the floating island layers are the same or different.

In at least one alternative embodiment, in the three-dimensional structure, the first doped region, the second doped region and a third doped region extend to an entire cell in a third dimension; or the first doped region and the third doped region extends to the entire cell in the third dimension and the second doped region extends to only a part of the cell in the third dimension; or the third doped region extends to the entire cell in the third dimension and the second doped region and the first doped region extend to only a part of the cell in the third dimension.

In at least one alternative embodiment, an upper edge of the second doped region is higher than or equal to or lower than an upper edge of the first doped region.

Another embodiment of the present disclosure is directed to a fast-turn-on floating island device, the device includes: a surface layer; a bottom layer; and a drift layer that is located between the surface layer and the bottom layer. The drift layer includes a plurality of epitaxial layers and a plurality of floating island layers, one of the floating island layers forms between each adjacent two of the epitaxial layers, or one of the epitaxial layer forms between each adjacent two of the floating island layers, first doped regions and second doped regions form in two or more of the floating island layers. The second doped regions are in direct contact with the first doped regions. A doping type of the first doped region is opposite to a doping type of the epitaxial layer, and a doping type of the second doped region is the same as the doping type of the epitaxial layer. A doping concentration of the second doped region is higher than a doping concentration of the epitaxial layer, and an upper edge of the second doped region is in direct contact with the epitaxial layer.

Another embodiment of the present disclosure is directed to a method for manufacturing the fast-turn-on floating island device, which features that the method can be applied to any of the fast-turn-on floating island device in the present disclosure.

Another embodiment of the present disclosure is directed to a method for manufacturing the fast-turn-on floating island device, the method comprises: an N-type epitaxial layer is formed on the N-type substrate layer; a floating island layer is formed in the N-type epitaxial layer by photolithography and P-type ion implantation, wherein the floating island layer includes a first doped region, a second doped region and a third doped region, and the second doped region is distributed in the first doped region or a part of the second doped region is distributed in the first doped region, and a doping type of the first doped region is opposite to a doping type of the epitaxial layer, and a doping type of the second doped region is the same as the doping type of the epitaxial layer, and a doping type of the third doped region is the same as the doping type of the epitaxial layer; the N-type epitaxial layers and the floating island layers are repeatedly stacked; a surface layer and a bottom layer are form at the two ends of the drift layer by metal sputtering or metal evaporation, and then high temperature annealing is implemented to the surface layer and a bottom layer, so as to form an ohmic contact between the bottom layer and the N-type epitaxial layer, and a Schottky contact is formed between the surface layer and the N-type epitaxial layer.

### BRIEF DESCRIPTION OF THE DRAWINGS

The present disclosure can be further understood with reference to the following detailed description and the appended drawings, wherein like elements are provided with like reference numerals. The drawings are only for illustration purpose. They may only show part of the devices and are not necessarily drawn to scale.

FIG. 1 schematically shows a cross-sectional view of a conventional floating island Schottky diode cell.

FIG. 2 schematically shows a cross-sectional view of a conventional floating island MOSFET cell.

FIG. 3 schematically shows a partial cross-sectional view of the fast-turn-on floating island device structure with an embodiment of the present disclosure.

FIG. 4 schematically shows a partial cross-sectional view of a variation of the floating island layer of the fast-turn-on floating island device with an embodiment of the present disclosure.

FIG. 5 schematically shows a partial cross-sectional view of a variation of the floating island layer of the fast-turn-on floating island device with an embodiment of the present disclosure.

FIG. 6 schematically shows a partial cross-sectional view of a variation of the floating island layer of the fast-turn-on floating island device with an embodiment of the present disclosure.

FIG. 7 schematically shows a partial cross-sectional view of a variation of the floating island layer of the fast-turn-on floating island device with an embodiment of the present disclosure.

FIG. 8 schematically shows a partial cross-sectional view of a variation of the floating island layer of the fast-turn-on floating island device with an embodiment of the present disclosure.

FIG. 9 schematically shows a partial cross-sectional view of a variation of the floating island layer of the fast-turn-on floating island device with an embodiment of the present disclosure.

FIG. 10 schematically shows a partial cross-sectional view of a variation of the floating island layer of the fast-turn-on floating island device with an embodiment of the present disclosure.

FIG. 11 schematically shows a partial cross-sectional view of a variation of the floating island layer of the fast-turn-on floating island device with an embodiment of the present disclosure.

FIG. 12 schematically shows a partial top view of a variation of the floating island layer of the fast-turn-on floating island device with an embodiment of the present disclosure.

FIG. 13 schematically shows a partial top view of a variation of the floating island layer of the fast-turn-on floating island device with an embodiment of the present disclosure.

FIG. 14 schematically shows a partial cross-sectional view of a variation of the surface layer of the fast-turn-on floating island device with an embodiment of the present disclosure.

FIG. 15 schematically shows a partial cross-sectional view of a variation of the surface layer of the fast-turn-on floating island device with an embodiment of the present disclosure.

FIG. 16 schematically shows a partial cross-sectional view of a variation of the surface layer of the fast-turn-on floating island device with an embodiment of the present disclosure,

FIG. 17 schematically shows a partial cross-sectional view of a variation of the surface layer of the fast-turn-on floating island device with an embodiment of the present disclosure.

FIG. 18 schematically shows a partial cross-sectional view of a variation of the surface layer of the fast-turn-on floating island device with an embodiment of the present disclosure.

FIG. 19 schematically shows a partial cross-sectional view of a variation of the bottom layer of the fast-turn-on floating island device with an embodiment of the present disclosure.

FIG. 20 schematically shows a partial cross-sectional view of a variation of the bottom layer of the fast-turn-on floating island device with an embodiment of the present disclosure.

FIG. 21 schematically shows a partial cross-sectional view of a fast-turn-on floating island Schottky diode with an embodiment of the present disclosure.

FIG. 22 schematically shows a partial cross-sectional view of a fast-turn-on floating island PN diode with an embodiment of the present disclosure.

FIG. 23 schematically shows a partial cross-sectional view of a fast-turn-on floating island junction barrier Schottky diode with an embodiment of the present disclosure.

FIG. 24 schematically shows a partial cross-sectional view of a fast-turn-on floating island junction barrier Schottky diode with an embodiment of the present disclosure.

FIG. 25 schematically shows a partial cross-sectional view of a fast-turn-on floating island MOSFET with an embodiment of the present disclosure.

FIG. 26 schematically shows a partial cross-sectional view of a fast-turn-on floating island IGBT with an embodiment of the present disclosure.

FIG. 27 schematically shows a partial cross-sectional view of a fast-turn-on floating island device structure with an embodiment of the present disclosure.

FIG. 28 schematically shows a partial cross-sectional view of a fast-turn-on floating island device structure with an embodiment of the present disclosure.

FIG. 29 schematically shows a partial cross-sectional view of a fast-turn-on floating island device structure with an embodiment of the present disclosure.

FIG. 30 schematically shows a partial cross-sectional view of a fast-turn-on floating island MOSFET with an embodiment of the present disclosure.

FIG. 31 schematically shows a partial cross-sectional view of a fast-turn-on floating island IGBT with an embodiment of the present disclosure.

FIG. 32 schematically shows a partial three-dimensional view of a fast-turn-on floating island junction barrier Schottky diode with an embodiment of the present disclosure.

FIG. 33 schematically shows a partial three-dimensional view of a fast-turn-on floating island junction barrier Schottky diode with an embodiment of the present disclosure.

FIG. 34 schematically shows a partial three-dimensional view of a fast-turn-on floating island junction barrier Schottky diode with an embodiment of the present disclosure.

FIG. 35 shows a method to fabricate a fast-turn-on floating island Schottky diode with an embodiment of the present disclosure.

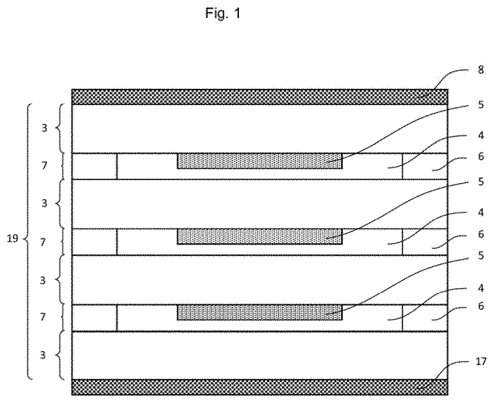

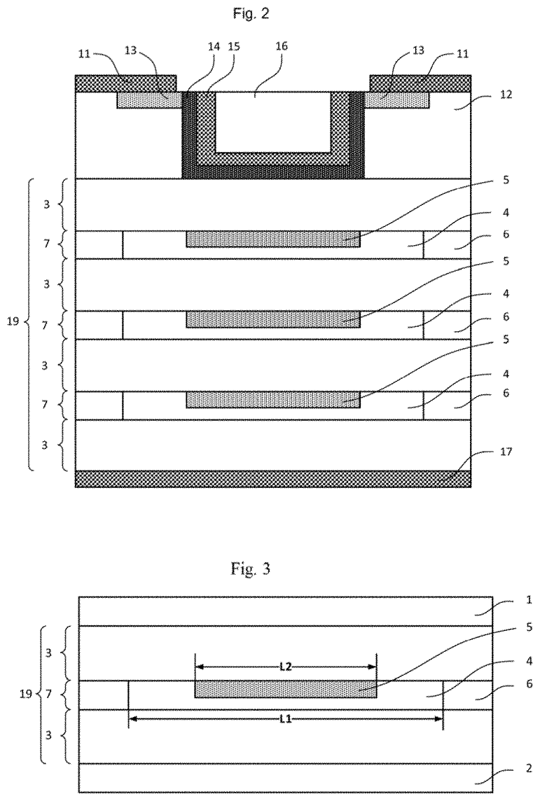

### DETAILED DESCRIPTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present disclosure, numerous specific details are set forth in order to provide a thorough understanding of the present disclosure. However, it will be obvious to one of ordinary skill in the art that the present disclosure may be practiced without these specific details. In other instances, well-known methods, procedures, components, and circuits have not been described in detail so as not to unnecessarily obscure aspects of the present disclosure.

Throughout the specification, references to “one embodiment,” “an embodiment,” “an example,” or “example” indicates that a specific feature, structure, or characteristic described in the embodiment or example is included in the present disclosure in at least one embodiment. Therefore, the phrases “in one embodiment,” “in an embodiment,” “an example,” or “example” appearing in various parts throughout the specification do not necessarily all refer to the same embodiment or example. In addition, specific features, structures, or characteristics may be combined in one or more embodiments or examples in any suitable combination and/or sub-combination. Those of ordinary skill in the art should understand that the drawings provided herein are for illustrative purposes, and the same reference numerals indicate the same elements, but are not limited to that the structure of the elements must be exactly the same. The term “and/or” as used herein includes any and all combinations of one or more of the associated listed items.

The material of semiconductor regions in the fast-turn-on floating island devices of the present disclosure includes, but is not limited to, Silicon Carbide, Gallium Nitride and silicon. Throughout the specification, the semiconductor regions in the present disclosure can be Silicon Carbide regions, silicon regions or any other semiconductor material regions applicable to the present disclosure. Although the embodiments of the present disclosure indicate that the doping type of each region is N-type or P-type. However, those who are skilled in the art should know that in other embodiments, the doping type of each region is not limited to the N-type or P-type specified in the present disclosure. For example, N-type and P-type doping can be interchanged. The alternate arrangement can be a complete alternate arrangement or an alternate arrangement including a device structure in the middle. For example, the two units also include other structures, or the two units also include the same structure as a certain unit. The paralleled units referred to in the present disclosure can mean that the two units are paralleled with a distance or the two units are overlapped. The top-view plane referred to in the present disclosure is not limited to the top-view plane on the surface of the semiconductor region, and may also be a certain cross-sectional view from the top of the device. The stripe referred to in the present disclosure can be a stripe structure with straight or non-straight sides. The polygon referred to can be a regular polygon or an irregular polygon, and the circle referred to can be a perfect circle or an irregular circle. The intersection referred to in the present disclosure may be a partial intersection or a complete intersection. Although the present disclosure exemplifies he first doped regions, the second doped regions and the third doped regions with a long stripe structure, the embodiment of the present disclosure is not limited to the long stripe structure shown in the figure, and can also be any other suitable shape, such as irregular stripes, regular or irregular enclosed shape with curved edges, etc.

FIG. 3 schematically shows a partial cross-sectional view of an embodiment of the fast-turn-on floating island device, comprising a surface layer 1, a bottom layer 2 and a drift layer 19. The drift layer 19 is located between the surface layer 1 and the bottom layer 2, comprising a plurality of epitaxial layers 3 and a plurality of floating island layers 7. There is a floating island layer 7 between each adjacent two epitaxial layers 3, or there is an epitaxial layer 3 between each adjacent two floating island layers 7 (refer to FIG. 27), and the number of epitaxial layers 3 and floating island layers 7 can be the same or different. When the number of epitaxial layers 3 is n, the number of floating island layers 7 can be n, (n−1), (n+1), or other values.

With the embodiment in FIG. 3, the floating island layer 7 and the epitaxial layers 3 are arranged in the way of staggering upward. The floating island device includes a floating island layer 7 and two epitaxial layers 3, and the floating island layer 7 is sandwiched between the two epitaxial layers 3. The epitaxial layer 3 can be semiconductor material doped with a concentration of 1×10¹⁵ cm⁻³·1×10²⁰ cm⁻³.

With the embodiment in FIG. 3, the floating island layer 7 includes the first doped region 4, the second doped region 5 and the third doped region 6, wherein the doping type of the first doped region 4 is opposite to that of the epitaxial layer 3, the doping type of the second doped region 5 is the same as that of the epitaxial layer 3 and the doping type of the third doped region 5 is the same as that of the epitaxial layer 3. The doping concentration of the third doped region 6 may be equal to or higher than or lower than the doping concentration of the epitaxial layer 3.

With the embodiment in FIG. 3, taking the epitaxial layer 3 to be N-type semiconductor material as an example, the first doped region 4 may be P-type semiconductor material with a doping concentration of 1×10¹⁵ cm⁻³ 1×10²⁰ cm⁻³, the second doped region 5 may be N-type semiconductor material with a doping concentration of 1×10¹⁵ cm⁻³˜1×10²⁰ cm⁻³, and the third doped region 6 may be N-type semiconductor material with a doping concentration of 1×10¹⁵ cm⁻³˜1×10¹⁹ cm⁻³. The doping concentration of the second doped region 5 may be higher than that of the epitaxial layer 3, and the doping concentration of the first doped region 4 may be equal to that of the second doped region 5. In another embodiments of the present disclosure, some floating island layers 7 in the floating island device may not include the third doped region 6, but only consist of the first doped region 4 and the second doped region 5. In another embodiments of the present disclosure, some floating island layers 7 in the floating island device may not include either the second doped region 5 or the third doped region 6, and include only the first doped region 4.

With the embodiment in FIG. 3, the length of the portion of the second doped region 5 that is distributed in the first doped region 4, denoted as L2, is smaller than the length of the first doped region 4, denoted as L1. The upper edge of the second doped region 5 coincides with the upper edge of the first doped region 4, the upper edge of the second doped region 5 is in direct contact with the epitaxial layer 3, and the lower edge of the second doped region 5 is not lower than the lower edge of the first doped region 4. In other embodiments of the present disclosure, the upper edge of the second doped region 5 may also be higher or lower than the upper edge of the first doped region 4.

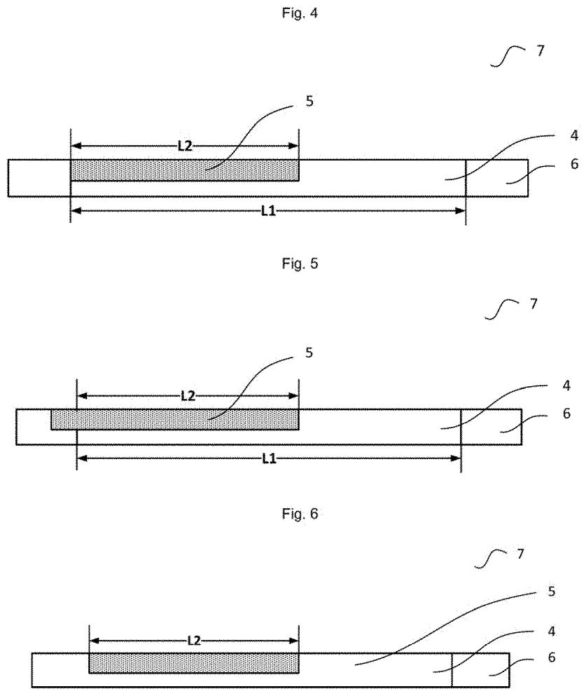

With the embodiments of the present disclosure, the shape and position of the second doped region 5 can have many changes. If the length of the second doped region 5 denoted as L2 is greater than or equal to the length of the first doped region 4 denoted as L1, when the device is in blocking state, the depletion region expands from top to bottom and is then stopped by the second doped region 5. Therefore, the length of the second doped region 5 denoted as L2 can be set to be smaller than the length of the first doped region 4 denoted as L1. When the lower edge of the second doped region 5 is lower than the lower edge of the first doped region 4, it is difficult for the second doped region 5 to be depleted by the first doped region 4 during blocking state, resulting in premature breakdown. Therefore, the lower edge of the second doped region 5 is set to be no lower than the lower edge of the first doped region 4. Variations of the second doped region 5 may be as shown in FIG. 4 to FIG. 13.

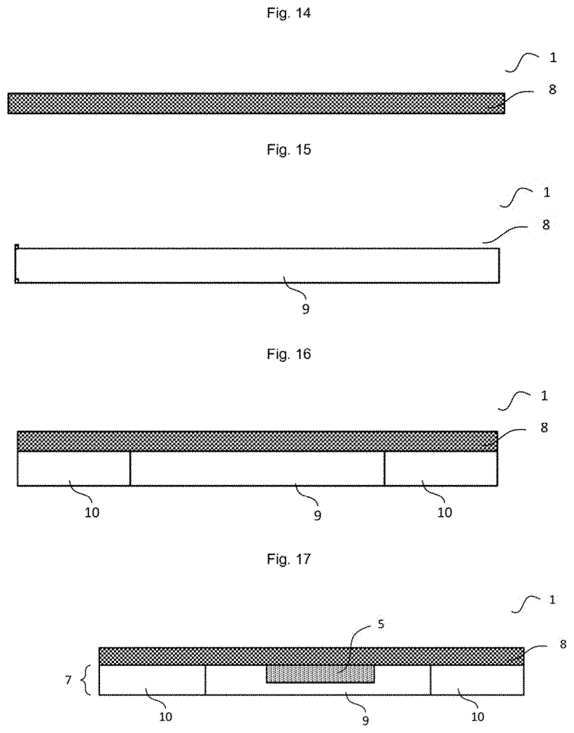

With the embodiment in FIG. 3, the surface layer 1 and the bottom layer 2 can also have various designs, so as to form various devices together with the drift layer 19. For example, the design of the surface layer 1 can be as shown in FIG. 14 to FIG. 18. The design of the bottom layer 2 can be as shown in FIG. 19 and FIG. 20.

With the embodiment in FIG. 3, by introducing a second doped region 5 with the opposite doping type to the first doped region 4, when the floating island device switches from a blocking state to a conducting state, the positive charges in the epitaxial layer 3 are pushed into the second doped region 5 as the electric field redistributes, so that the space charges in the epitaxial layer 3 are concentrated in the second doped region 5 instead of being dispersed throughout the epitaxial layer 3, so that the current flow is free of the obstruction caused by the space charges, and the drift layer 19 can conduct current at a low voltage drop. When the doping concentration of the second doped region 5 is very high, the tunneling effect of the PN junction formed between the second doped region 5 and the first doped region 4 is enhanced, thereby further reducing the width of the depletion region around the islands, increasing the current conducting capability.

With the embodiment in FIG. 3, the floating island layer 7 can have various designs. As shown in FIG. 4, the position of the second doped region 5 relative to the first doped region 4 can be moved to the left. For example, the left edge of the second doped region 5 may coincide with the left edge of the first doped region 4, or the right edge of the second doped region 5 may coincide with the right edge of the first doped region 4.

With the embodiment in FIG. 3, the floating island layer 7 can have various designs. As shown in FIG. 5, the position of the second doped region 5 relative to the first doped region 4 can be moved to the left. For example, the left edge of the second doped region 5 protrudes to the left of the left edge of the first doped region 4, or the right edge of the second doped region 5 protrudes to the right of the right edge of the first doped region 4. In this design, the length of the portion of the second doped region 5 that is distributed in the first doped region 4, denoted as L2, is less than the length of the first doped region 4, denoted as L1.

With the embodiment in FIG. 3, the floating island layer 7 can have various designs. For example, as shown in FIG. 6, the third doped region 6 may exist at one side of the first doped region 4, but may not at the other side of the first doped region 4.

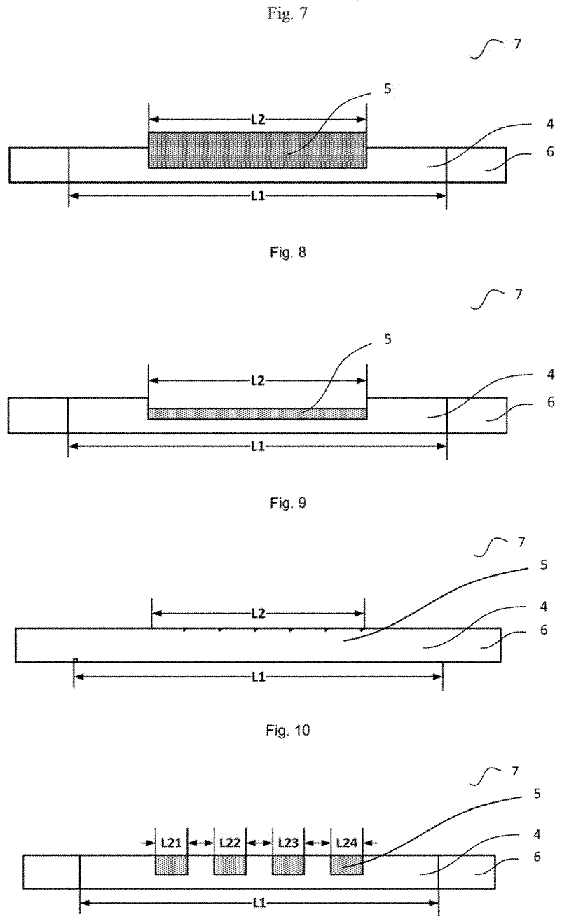

With the embodiment in FIG. 3, the floating island layer 7 can have various designs. For example, as shown in FIG. 7, the upper edge of the second doped region 5 may be higher than the upper edge of the first doped region 4, that is, part of the second doped region 5 that is lower than the upper edge of the first doped region 4 is distributed in the first doped region 4.

With the embodiment in FIG. 3, the floating island layer 7 can have various designs. The upper edge of the second doped region 5 may be lower than the first doped region 4. For example, as shown in FIG. 8, the upper edge of the second doped region 5 is in direct contact with the epitaxial layer 3, that is, the second doped region 5 is not completely surrounded by the first doped region 4, only the bottom and both sides are surrounded by the first doped region 4. In other embodiments, as long as the upper edge of the second doped region 5 is in direct contact with the epitaxial layer 3, it can be included in the protection scope of the present disclosure.

With the embodiment in FIG. 3, the floating island layer 7 can have various designs. For example, as shown in FIG. 9, the shape of the second doped region 5 may be zigzag.

With the embodiment in FIG. 3, the floating island layer 7 can have various designs. The second doped region 5 may be composed of several discontinuous parts. For example, as shown in FIG. 10, the second doped regions 5 distributed in the same first doped region 4 are arranged at intervals in the lateral direction. In this case, the sum of the lengths of the respective parts (L21, L22, L23, L24, etc.) is set to be smaller than the length of the first doped region 4 denoted as L1.

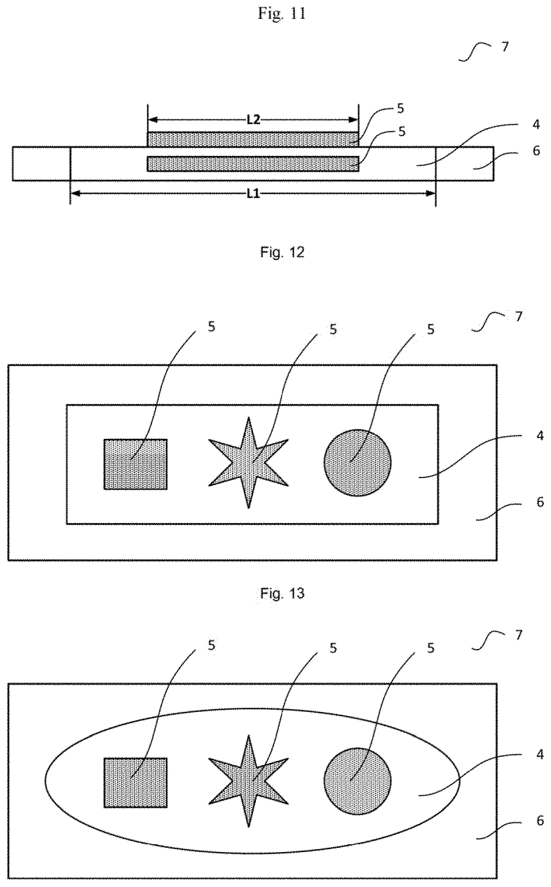

With the embodiment in FIG. 3, the floating island layer 7 can have various designs. The second doped region 5 may be composed of several discontinuous parts in the longitudinal direction. For example, as shown in FIG. 11, the portions of the second doped region 5 distributed in the same floating island layer 7 are arranged at intervals in the longitudinal direction. In one embodiment, there may be one or several portions of the second doped regions 5 distributed in the first doped region 4 (That is, the periphery of the one or several portions of the second doped regions 5 may be surrounded by the first doped regions 4), and the lower edge of the topmost portion of the second doped region 5 may coincide or be lower to the upper edge of the first doped region 4. In other embodiments of the present disclosure, the second doped regions 5 are not limited to be arranged at intervals in the longitudinal direction or the lateral direction, and may also be arranged at intervals in any other direction.

With the embodiment in FIG. 3, the floating island layer 7 can have various designs. The top-view shape of the second doped region 5 can be varied in many ways. For example, as shown in FIG. 12, the top view of the second doped region 5 may be a square, a star, a circle, or the like.

With the embodiment in FIG. 3, the floating island layer 7 can have various designs. The top-view shape of the first doped region 4 can be varied in many ways. For example, as shown in FIG. 13, the top view of the first doped region 4 may be oval or the like.

With the embodiment in FIG. 3, the surface layer 1 can have various designs. For example, as shown in FIG. 14, the surface layer 1 may include an anode metal 8.

With the embodiment in FIG. 3, the surface layer 1 can have various designs. For example, as shown in FIG. 15, the surface layer 1 may include an anode metal 8 and an anode doped region 9.

With the embodiment in FIG. 3, the surface layer 1 can have various designs. For example, as shown in FIG. 16, the surface layer 1 may include an anode metal 8, an anode doped region 9 and an anode epitaxial layer 10.

With the embodiment in FIG. 3, the surface layer 1 can have various designs. For example, as shown in FIG. 17, the surface layer 1 may include an anode metal 8, an anode doped region 9, an anode epitaxial layer 10 and a second doped region 5.

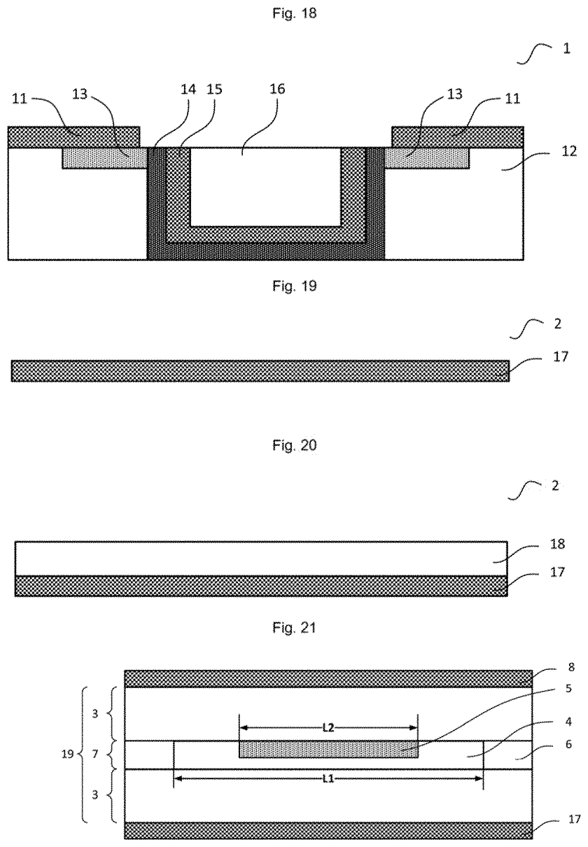

With the embodiment in FIG. 3, the surface layer 1 can have various designs. For example, as shown in FIG. 18, the surface layer 1 may include a source metal 11, a channel well doped region 12, a source doped region 13, a gate oxide layer 14, a gate metal and a trench filler 16.

With the embodiment in FIG. 3, the bottom layer 2 can have various designs. For example, as shown in FIG. 19, the bottom layer 2 may include a cathode-drain metal 17.

With the embodiment in FIG. 3, the bottom layer 2 can have various designs. For example, as shown in FIG. 20, the bottom layer 2 may include a cathode-drain metal 17 and a drain doped region 18.

FIG. 21 schematically shows a partial cross-sectional view of a fast-turn-on floating island Schottky diode. Compared to the embodiment in FIG. 3, the surface layer 1 is specified as shown in FIG. 14, comprising an anode metal 8, and the bottom layer 2 is specified as shown in FIG. 19, comprising a cathode-drain metal 17.

With the embodiment in FIG. 21, by introducing a second doped region with the opposite doping type to the first doped region, when the floating island Schottky diodes witches from a blocking state to a conducting state, the positive charges in the epitaxial layer are pushed into the second doped region as the electric field redistributes, so that the space charges in the epitaxial layer are concentrated in the second doped region instead of being dispersed throughout the epitaxial layer, so that the current flow is free of the obstruction caused by the space charges, and the drift layer can conduct current at a low voltage drop. When the doping concentration of the second doped region is very high, the tunneling effect of the PN junction formed between the second doped region and the first doped region is enhanced, thereby further reducing the width of the depletion region around the islands, increasing the current conducting capability.

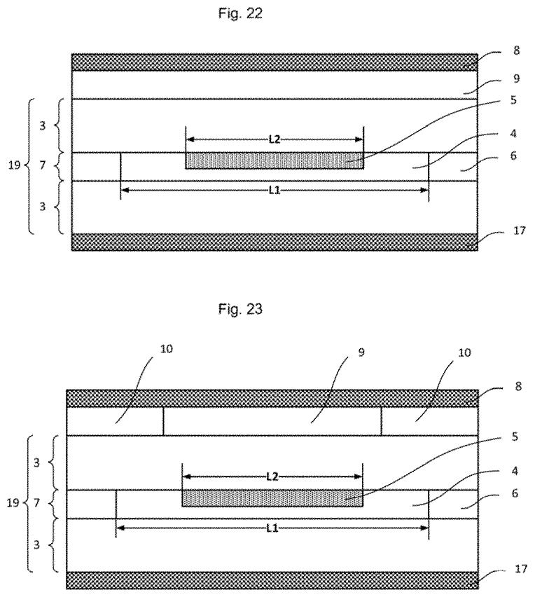

FIG. 22 schematically shows a partial cross-sectional view of a fast-turn-on floating island PN diode. Compared to the embodiment in FIG. 3, the surface layer 1 is specified as shown in FIG. 15, comprising an anode metal 8 and an anode doped region 9, and the bottom layer 2 is specified as shown in FIG. 19, comprising a cathode-drain metal 17. The doping type of the anode doped region 9 is opposite to that of the epitaxial layer 3. Taking the epitaxial layer 3 to be N-type semiconductor material as an example, the anode doped region 9 can be P-type semiconductor material with a doping concentration of 1×10¹⁵ cm⁻³˜1×10²⁰ cm⁻³.

With the embodiment in FIG. 22, by introducing a second doped region with the opposite doping type to the first doped region, when the floating island PN diode switches from a blocking state to a conducting state, the positive charges in the epitaxial layer are pushed into the second doped region as the electric field redistributes, so that the space charges in the epitaxial layer are concentrated in the second doped region instead of being dispersed throughout the epitaxial layer, so that the current flow is free of the obstruction caused by the space charges, and the drift layer can conduct current at a low voltage drop. When the doping concentration of the second doped region is very high, the tunneling effect of the PN junction formed between the second doped region and the first doped region is enhanced, thereby further reducing the width of the depletion region around the islands, increasing the current conducting capability.

FIG. 23 schematically shows a partial cross-sectional view of a fast-turn-on floating island junction barrier Schottky diode. Compared to the embodiment in FIG. 3, the surface layer 1 is specified as shown in FIG. 16, comprising an anode metal 8, an anode doped region 9 and an anode epitaxial layer 10, and the bottom layer 2 is specified as shown in FIG. 19, comprising a cathode-drain metal 17. The doping type of the anode doped region 9 is opposite to that of the epitaxial layer 3, the doping type of the anode epitaxial layer 10 is the same as that, of the epitaxial layer 3, and the anode epitaxial layer 10 is located on both sides or only one side of the anode doped region 9. Taking the epitaxial layer 3 to be N-type semiconductor material as an example, the anode doped region 9 can be P-type semiconductor material with a doping concentration of 1×10¹⁵ cm⁻³˜1×10²⁰ cm⁻³ and the anode epitaxial layer 10 can be N-type semiconductor material with a doping concentration of 1×10¹⁵ cm⁻³˜1×10¹⁹ cm⁻³.

With the embodiment in FIG. 23, by introducing a second doped region with the opposite doping type to the first doped region, when the floating island junction barrier Schottky diode switches from a blocking state to a conducting state, the positive charges in the epitaxial layer are pushed into the second doped region as the electric field redistributes, so that the space charges in the epitaxial layer are concentrated in the second doped region instead of being dispersed throughout the epitaxial layer, so that the current flow is free, of the obstruction caused by the space charges, and the drift layer can conduct current at a low voltage drop. When the doping concentration of the second doped region is very high, the tunneling effect of the PN junction formed between the second doped region and the first doped region is enhanced, thereby further reducing the width of the depletion region around the islands, increasing the current conducting capability.

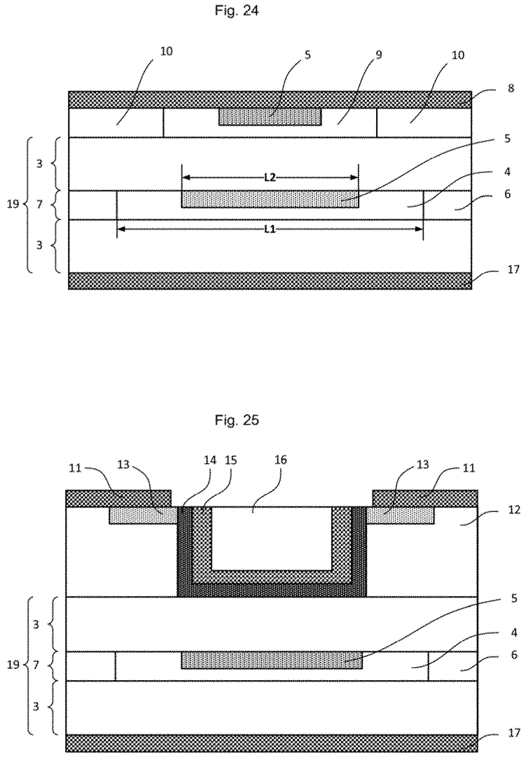

FIG. 24 schematically shows a partial cross-sectional view of another fast-turn-on floating island junction barrier Schottky diode. Compared to the embodiment in FIG. 3, the surface layer 1 is specified as shown in FIG. 17, comprising an anode metal 8, an anode doped region 9, an anode epitaxial layer 10 and a second doped region 5, and the bottom layer 2 is specified as shown in FIG. 19, comprising a cathode-drain metal 17. The doping type of the anode doped region 9 is opposite to that of the epitaxial layer 3, the doping type of the anode epitaxial layer 10 is the same as that of the epitaxial layer 3, and the anode epitaxial layer 10 is located on either sides or only one side of the anode doped region 9. Taking the epitaxial layer 3 to be N-type semiconductor material as an example, the anode doped region 9 can be P-type semiconductor material with a doping concentration of 1×10¹⁵ cm⁻³˜1×10²⁰ cm⁻³ and the anode epitaxial layer 10 can be N-type semiconductor material with a doping concentration of 1×10¹⁵ cm⁻³˜1×10¹⁹ cm⁻³.

With the embodiment in FIG. 24, by introducing a second doped region with the opposite doping type to the first doped region, when the floating island junction barrier Schottky diode switches from a blocking state to a conducting state, the positive charges in the epitaxial layer are pushed into the second doped region as the electric field redistributes, so that the space charges in the epitaxial layer are concentrated in the second doped region instead of being dispersed throughout the epitaxial layer, so that the current flow is free of the obstruction caused by the space charges, and the drift layer can conduct current at a low voltage drop. When the doping concentration of the second doped region is very high, the tunneling effect of the PN junction formed between the second doped region and the first doped region is enhanced, thereby further reducing the width of the depletion region around the islands, increasing the current conducting capability.

FIG. 25 schematically shows a partial cross-sectional view of a fast-turn-on floating island MOSFET. Compared to the embodiment in FIG. 3, the surface layer 1 is specified as shown in FIG. 18, comprising a source metal 11, a channel well doped region 12, a source doped region 13, a gate oxide layer 14, a gate metal and a trench filler 16, and the bottom layer 2 is specified as shown in FIG. 19, comprising a cathode-drain metal 17. The doping type of the channel well doped region 12 is opposite to that of the epitaxial layer 3, and the doping type of the source doped region 13 is the same as that of the epitaxial layer 3. The gate oxide layer 14 can be insulating oxide layer, and the trench filler 16 can be insulator, conductor or semiconductor. Taking the epitaxial layer 3 to be N-type semiconductor material as an example, the channel well doped region 12 can be P-type semiconductor material with a doping concentration of 1×10¹⁵ cm⁻³˜1×10¹⁹ cm⁻³ and the source doped region 13 can be N-type semiconductor material with a doping concentration of 1×10¹⁵ cm⁻³˜1×10²⁰ cm⁻³.

In other embodiments of the present disclosure, the fast-turn-on floating island MOSFET is not limited to a trench MOSFET, but can also be any other MOSFET structure such as a planar MOSFET. The MOSFET includes source metal, cathode-drain metal, channel-well doped region, source doped region, gate oxide layer and gate metal.

With the embodiment in FIG. 25, by introducing a second doped region with the opposite doping type to the first doped region, when the floating island MOSFET switches from a blocking state to a conducting state, the positive charges in the epitaxial layer are pushed into the second doped region as the electric field redistributes, so that the space charges in the epitaxial layer are concentrated in the second doped region instead of being dispersed throughout the epitaxial layer, so that the current flow is free of the obstruction caused by the space charges, and the drift layer can conduct current at a low voltage drop. When the doping concentration of the second doped region is very high, the tunneling effect of the PN junction formed between the second doped region and the first doped region is enhanced, thereby further reducing the width of the depletion region around the islands, increasing the current conducting capability.

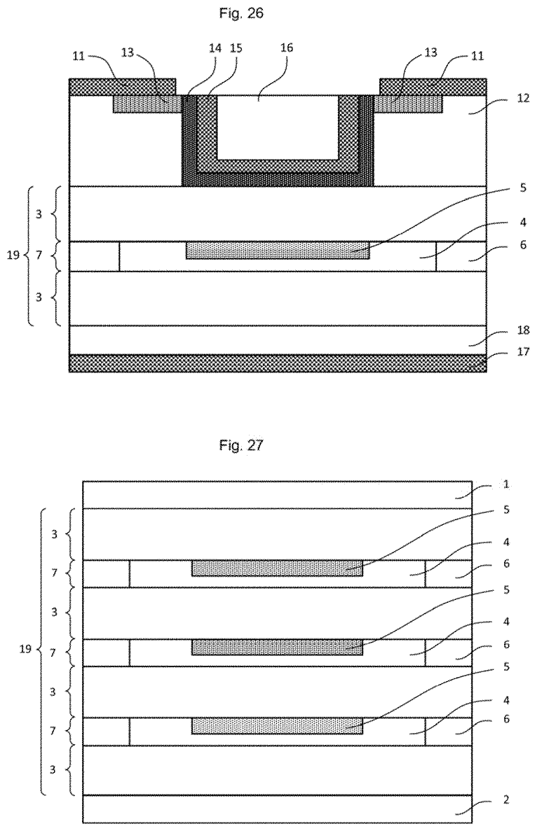

FIG. 26 schematically shows a partial cross-sectional view of a fast-turn-on floating island IGBT. Compared to the embodiment in FIG. 3, the surface layer 1 is specified as shown in FIG. 18, comprising a source metal 11, a channel well doped region 12, a source doped region 13, a gate oxide layer 14, a gate metal and a trench filler 16, and the bottom layer 2 is specified as shown in FIG. 20, comprising a cathode-drain metal 17 and a drain doped region 18. The doping type of the channel well doped region 12 is opposite to that of the epitaxial layer 3, the doping type of the source doped region 13 is the same as that of the epitaxial layer 3, and the doping type of the drain doped region 18 is opposite to that of the epitaxial layer 3. The gate oxide layer 14 can be insulating oxide layer, and the trench filler 16 can be insulator, conductor or semiconductor. Taking the epitaxial layer 3 to be N-type semiconductor material as an example, the channel well doped region 12 can be P-type semiconductor material with a doping concentration of 1×10¹⁵ cm⁻³˜1×10¹⁹ cm⁻³ the source doped region 13 can be N-type semiconductor material with a doping concentration of 1×10¹⁵ cm⁻³ 1×10²⁰ cm⁻³ and the drain doped region 18 can be P-type semiconductor material with a doping concentration of 1×10¹⁵ cm⁻³˜1×10²⁰ cm⁻³.

In other embodiments of the present disclosure, the fast-turn-on floating island IGBT is not limited to a trench IGBT, but can also be any other IGBT structure such as a planar IGBT. The IGBT includes source metal, cathode-drain metal, channel-well doped region, source doped region, gate oxide layer, gate metal and drain doped region.

With the embodiment in FIG. 26, by introducing a second doped region with the opposite doping type to the first doped region, when the floating island IGBT switches from a blocking state to a conducting state, the positive charges in the epitaxial layer are pushed into the second doped region as the electric field redistributes, so that the space charges in the epitaxial layer are concentrated in the second doped region instead of being dispersed throughout the epitaxial layer, so that the current flow is free of the obstruction caused by the space charges, and the drift layer can conduct current at a low voltage drop. When the doping concentration of the second doped region is very high, the tunneling effect of the PN junction formed between the second doped region and the first doped region is enhanced, thereby further reducing the width of the depletion region around the islands, increasing the current conducting capability.

FIG. 27 schematically shows a partial cross-sectional view of another embodiment of the fast-turn-on floating island device. Compared to the embodiment in FIG. 3, the drift layer 19 is formed by staggered arrangement of four epitaxial layers 3 and three floating island layers 7. In other embodiments, the number of epitaxial layers 3 and floating island layers 7 can be set as other value according to actual requirements.

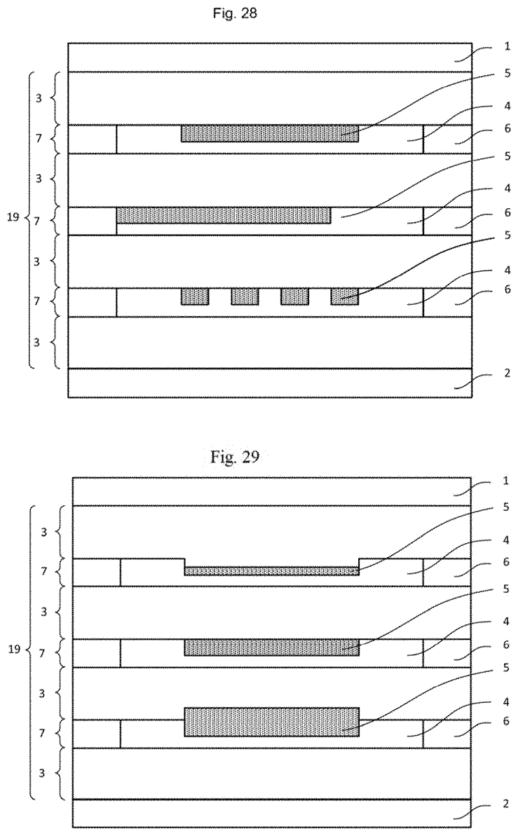

FIG. 28 schematically shows a partial cross-sectional view of another embodiment of the fast-turn-on floating island device. Compared to the embodiment in FIG. 27, the three floating island layers 7 in the drift layer 19 have different designs from one another. For example, the three floating island layers have the structures shown by the embodiments in FIG. 3, FIG. 4 and FIG. 10, respectively.

FIG. 29 schematically shows a partial cross-sectional view of another embodiment of the fast-turn-on floating island device. Compared to the embodiment in FIG. 27, the upper edge of the second doped region 5 in the three floating island layers 7 in the drift layer 19 may be higher than or equal to or lower than the upper edge of the first doped region 4. For example, the three floating island layers have the structures shown by the embodiments in FIG. 3, FIG. 7 and FIG. 8, respectively.

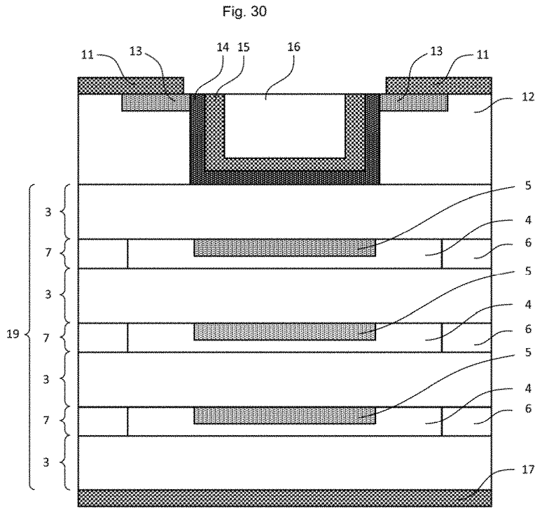

FIG. 30 schematically shows a partial cross-sectional view of a three-layer fast-turn-on floating island MOSFET. Compared to the embodiment in FIG. 27, the surface layer 1 is specified as shown in FIG. 18, comprising a source metal 11, a channel well doped region 12, a source doped region 13, a gate oxide layer 14, a gate metal and a trench filler 16, and the bottom layer 2 is specified as shown in FIG. 19, comprising a cathode-drain metal 17. The doping type of the channel well doped region 12 is opposite to that of the epitaxial layer 3, and the doping type of the source doped region 13 is the same as that of the epitaxial layer 3. The gate oxide layer 14 can be insulating oxide layer, and the trench filler 16 can be insulator, conductor or semiconductor, Taking the epitaxial layer 3 to be N-type semiconductor material as an example, the channel well doped region 12 can be P-type semiconductor material with a doping concentration of 1×10¹⁵ cm⁻³˜1×10¹⁹ cm⁻³ and the source doped region 13 can be N-typesemiconductor material with a doping concentration of 1×10¹⁵ cm⁻³˜1×10²⁰ cm⁻³. In other embodiments of the present disclosure, the fast-turn-on floating island MOSFET is not limited to a trench MOSFET, but can also be any other MOSFET structure such as a planar MOSFET. The MOSFET includes source metal, cathode-drain metal, channel-well doped region, source doped region, gate oxide layer and gate metal. In other embodiments of the present disclosure, the number of the epitaxial layers 3 and the floating island layers 7 can be set to other values.

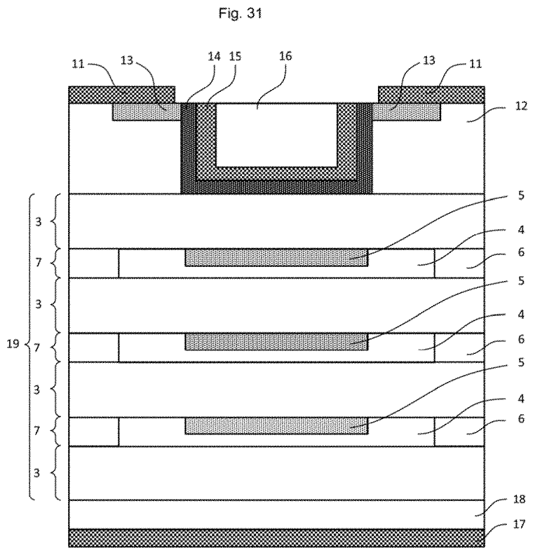

FIG. 31 schematically shows a partial cross-sectional view of a three-layer fast-turn-on floating island IGBT. Compared to the embodiment in FIG. 27, the surface layer 1 is specified as shown in FIG. 18, comprising a source metal 11, a channel well doped region 12, a source doped region 13, a gate oxide layer 14, a gate metal and a trench filler 16, and the bottom layer 2 is specified as shown in FIG. 20, comprising a cathode-drain metal 17 and a drain doped region 18. The doping type of the channel well doped region 12 is opposite to that of the epitaxial layer 3, the doping type of the source doped region 13 is the same as that of the epitaxial layer 3, and the doping type of the drain doped region 18 is opposite to that of the epitaxial layer 3. The gate oxide layer 14 can be insulating oxide layer, and the trench filler 16 can be insulator, conductor or semiconductor. Taking the epitaxial layer 3 to be N-type semiconductor material as an example, the channel well doped region 12 can be P-type semiconductor material with a doping concentration of 1×10¹⁵ cm⁻³˜1×10¹⁹ cm⁻³, the source doped region 13 can be N-typesemiconductor material with a doping concentration of 1×10¹⁵ cm⁻³˜1×10²⁰ cm⁻³ and the drain doped region 18 can be P-type semiconductor material with a doping concentration of 1×10¹⁵ cm⁻³˜1×10²⁰ cm⁻³. In other embodiments of the present disclosure, the three-layer fast-turn-on floating island IGBT is not limited to a trench IGBT, but can also be any other IGBT structure such as a planar IGBT. The IGBT includes source metal, cathode-drain metal, channel-well doped region, source doped region, gate oxide layer, gate metal and drain doped region. In other embodiments of the present disclosure, the number of the epitaxial layers 3 and the floating island layers 7 can be set to other values.

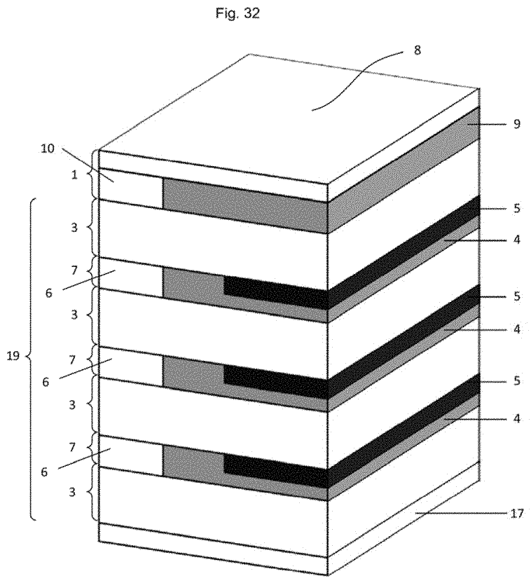

With the embodiment in FIG. 27, the structure can have various designs in the direction perpendicular to the paper. For example, FIG. 32 shows the three-dimensional view of a three-layer fast-turn-on floating island junction barrier Schottky diode. Compared to the embodiment in FIG. 27, the first doped region 4, the second doped region 5 and the third doped region 6 extend to the whole cell in the one of the dimension.

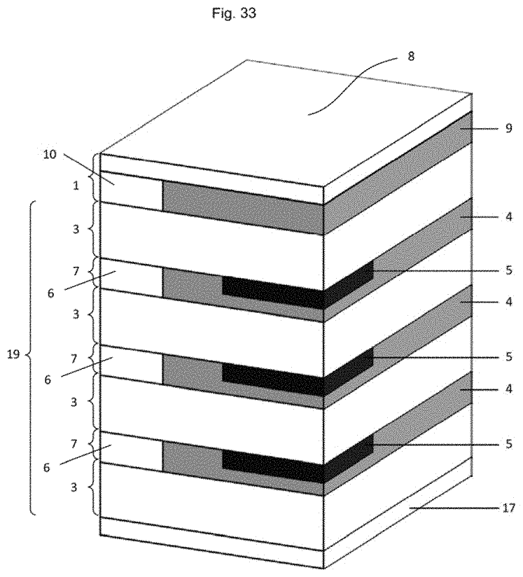

With the embodiment in FIG. 27, the structure can have various designs in the direction perpendicular to the paper. For example, FIG. 33 shows the three-dimensional view of another three-layer fast-turn-on floating island junction barrier Schottky diode. Compared to the embodiment in FIG. 27, the first doped region 4 and the third doped region 6 extend to the whole cell in the one of the dimension, whereas the second doped region 5 extends only to part of the cell in one of the dimension.

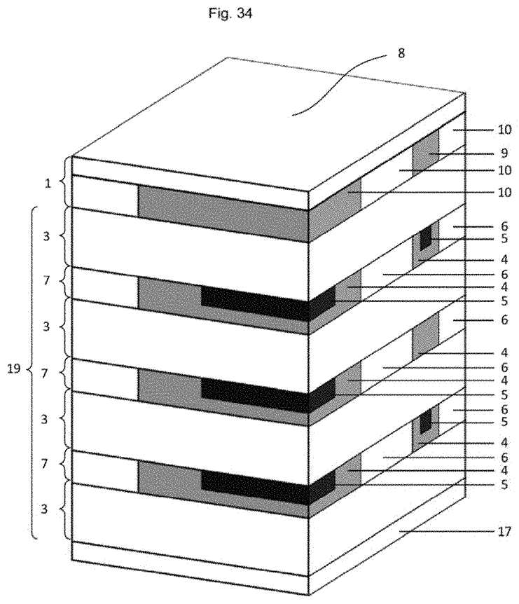

With the embodiment in FIG. 27, the structure can have various designs in the direction perpendicular to the paper. For example, FIG. 34 shows the three-dimensional view of another three-layer fast-turn-on floating island junction barrier Schottky diode. Compared to the embodiment in FIG. 27, the first doped region 4 extends to the whole cell in the one of the dimension, whereas the second doped region 5 and the third doped region 6 extend only to part of the cell in one of the dimension. There is no second doped region 5 in some of the first doped regions 4.

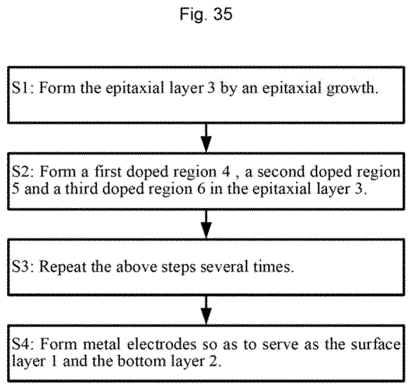

FIG. 35 schematically shows a method for manufacturing the fast-turn-on floating island device, comprising steps S1 to S4.

Step S1: Form the epitaxial layer 3 by an epitaxial growth.

Step S2: Form a first doped region 4, a second doped region 5 and a third doped region 6 in the epitaxial layer 3 by photolithography, ion implantation, etc., so as to compose a floating island layer 7.

Step S3: Repeat the above steps several times, so that several epitaxial layers 3 and several floating island layers 7 are staggered to compose a drift layer 19.

Step S4: Form metal electrodes by sputtering, evaporation and/or annealing at both ends of the drift layer 19, so as to serve as the surface layer 1 and the bottom layer 2.

The method described in this embodiment takes FIG. 21 as an example. First, an epitaxial layer 3 is obtained by epitaxial growth, and is doped to be N-type with a doping concentration of 1×10¹⁵ cm⁻³˜1×10¹⁹ cm⁻³. Then through photolithography and P-type ion implantation, the first doped region 4, the second doped region 5 and the third doped region 6 are formed in the epitaxial layer 3, composing the floating island layer 7. Then the epitaxial layer 3 is repeatedly stacked, in each of which the floating island layer 7 is formed. After the fabrication of the drift layer 19 is completed, a surface layer 1 and a bottom layer 2 are formed on both ends of the drift layer 19 by metal sputtering or metal evaporation, and then annealed at a high temperature (1000° C. for example), so that an ohmic contact is formed between the bottom layer 2 and the epitaxial layer 3, and Schottky contact is formed between the surface layer and the epitaxial layer 3.

To illustrate the embodiments of this invention, certain concepts, e.g., N-type semiconductor region, N-type source contact region, P-type electric field shielding region, P-type base region are utilized. However, it should be noticed that each region is not limited to the examples in embodiments. A person skilled in the art should know the regions could be replaced by regions with the opposite doping type.

A person skilled in the art should know that any combination or assembly of the structures in FIG. 3 to FIG. 34 should be comprehended as a technical solution or an embodiment proposed by this invention. E.g., with other embodiments, the location and shape of the second doped regions in above embodiments could be varied.

Obviously, many modifications and variations of the present disclosure are possible in light of the above teachings. It is therefore to be understood that within the scope of the appended claims the invention may be practiced otherwise than as specifically described. It should be understood, of course, the foregoing disclosure relates only to a preferred embodiment (or embodiments) of the invention and that numerous modifications may be made therein without departing from the spirit and the scope of the invention as set forth in the appended claims. Various modifications are contemplated and they obviously will be resorted to by those skilled in the art without departing from the spirit and the scope of the invention as hereinafter defined by the appended claims as only a preferred embodiments) thereof has been disclosed.

What is claimed is:

1. A fast-turn-on floating island device, comprising: a surface layer; a bottom layer; and a drift layer, which is located between the surface layer and the bottom layer, wherein, the drift layer comprises a plurality of epitaxial layers and a plurality of floating island layers, one of the floating island layers forms between each adjacent two of the epitaxial layers, or one of the epitaxial layers forms between each adjacent two of the floating island layers, a first doped region and a second doped region form in at least one of the floating island layers, a doping type of the first doped region is opposite to a doping type of the epitaxial layer, and a doping type of the second doped region is the same as the doping type of the epitaxial layer.

2. The fast-turn-on floating island device according to claim 1, wherein the second doped region is distributed in the first doped region, or a part of the second doped region is distributed in the first doped region.

3. The fast-turn-on floating island device according to claim 1, wherein a lower edge of the second doped region is not lower than a lower edge of the first doped region, and an upper edge of the second doped region directly contacts the epitaxial layer.

4. The fast-turn-on floating island device according to claim 1, wherein a length of a portion of the second doped region which is distributed in the first doped region is less than a length of the first doped region.

5. The fast-turn-on floating island device according to claim 1, wherein the floating island layer comprises a plurality of the second doped regions arranged at intervals.

6. The fast-turn-on floating island device according to claim 5, wherein a total length of the second doped region arranged at intervals is less than a length of the first doped region.

7. The fast-turn-on floating island device according to claim 1, wherein at least one of the floating island layers further comprises a third doped region, and a doping type of the third doped region is the same as the doping type of the epitaxial layer.

8. The fast-turn-on floating island device according to claim 1, wherein:
in a case that the fast-turn-on floating island device is a fast-turn-on floating-island Schottky diode, the surface layer comprises an anode metal, and the bottom layer comprises a cathode-drain metal;
in a case that the fast-turn-on floating island device is a fast-turn-on floating island PN diode, the surface layer comprises an anode metal and an anode doped region, a doping type of the anode doped region is opposite to a doping type of the epitaxial layer, and the bottom layer comprises a cathode-drain metal; and
in a case that the fast-turn-on floating island device is a fast-turn-on floating island junction barrier Schottky diode, the surface layer comprises an anode metal, an anode doped region and an anode epitaxial region, and a doping type of the anode doped region is opposite to the doping type of the epitaxial layer, and the doping type of the anode epitaxial layer is the same as the doping type of the epitaxial layer, and the bottom layer comprises a cathode-drain metal.

9. The fast-turn-on floating island device according to claim 8, wherein in a case that the fast-turn-on floating island device is the fast-turn-on floating island junction barrier Schottky diode, the surface layer further comprises the second doped region.

10. The fast-turn-on floating island device according to claim 1, wherein:
in a case that the fast-turn-on floating island device is a fast-turn-on floating island MOSFET, the surface layer comprises a source metal, a channel well doped region, a source doped region, a gate oxide layer, a gate metal, and the bottom layer comprises a cathode-drain metal; and
in a case that the fast-turn-on floating island device is a fast-turn-on floating island IGBT, the surface layer comprises a source metal, a channel well doped region, a source doped region, a gate oxide layer, a gate metal, and the bottom layer comprises a cathode-drain metal and a drain doped region.

11. The fast-turn-on floating island device according to claim 1, wherein the drift layer comprises two or more of the floating island layers, and the structures of the floating island layers are the same or different.

12. The fast-turn-on floating island device according to claim 1, wherein in a three-dimensional view, the first doped region, the second doped region and the third doped region extend to an entire cell in a third dimension; or the first doped region and the third doped region extend to the entire cell in the third dimension and the second doped region extends to only a part of the cell in the third dimension; or the third doped region extends to the entire cell in the third dimension and the second doped region and the first doped region extend to only a part of the cell in the third dimension.

13. The fast-turn-on floating island device according to claim 1, wherein an upper edge of the second doped region is higher than or equal to or lower than an upper edge of the first doped region.

14. A fast-turn-on floating island device, comprising: a surface layer; a bottom layer; and a drift layer, which is located between the surface layer and the bottom layer, wherein, the drift layer comprises a plurality of epitaxial layers and a plurality of floating island layers, one of the floating island layers forms between each adjacent two of the epitaxial layers, or one of the epitaxial layers forms between each adjacent two of the floating island layers, first doped regions and second doped regions formed in two or more of the floating island layers, the second doped regions are in direct contact with the first doped regions, a doping type of the first doped region is opposite to a doping type of the epitaxial layer, and a doping type of the second doped region is the same as the doping type of the epitaxial layer, a doping concentration of the second doped region is higher than a doping concentration of the epitaxial layer, and an upper edge of the second doped region is in direct contact with the epitaxial layer.

15. The fast-turn-on floating island device according to claim 14, wherein a lower edge of the second doped region is not lower than a lower edge of the first doped region, and a length of a portion of the second doped region which is distributed in the first doped region is less than a length of the first doped region.

16. The fast-turn-on floating island device according to claim 15, wherein:
in a case that the fast-turn-on floating island device is a fast-turn-on floating-island Schottky diode, the surface layer comprises an anode metal, and the bottom layer comprises a cathode-drain metal;
in a case that the fast-turn-on floating island device is a fast-turn-on floating island PN diode, the surface layer comprises an anode metal and an anode doped region, a doping type of the anode doped region is opposite to the doping type of the epitaxial layer, and the bottom layer comprises a cathode-drain metal;
in a case that the fast-turn-on floating island device is a fast-turn-on floating island junction barrier Schottky diode, the surface layer comprises an anode metal, an anode doped region and an anode epitaxial region, or the surface layer comprises an anode metal, an anode doped region, an anode epitaxial region and a second doped region, and a doping type of the anode doped region is opposite to the doping type of the epitaxial layer, and a doping type of the anode epitaxial layer is the same as the doping type of the epitaxial layer, and the bottom layer comprises a cathode-drain metal;
in a case that the fast-turn-on floating island device is a fast-turn-on floating island MOSFET, the surface layer comprises a source metal, a channel well doped region, a source doped region, a gate oxide layer, a gate metal, and the bottom layer comprises a cathode-drain metal; and
in a case that the fast-turn-on floating island device is a fast-turn-on floating island IGBT, the surface layer comprises a source metal, a channel well doped region, a source doped region, a gate oxide layer, a gate metal, and the bottom layer comprises a cathode-drain metal and a drain doped region.

17. A method for manufacturing the fast-turn-on floating island Schottky diode, comprising:
growing an N-type epitaxial layer on an N-type substrate layer;
forming a floating island layer in the N-type epitaxial layer by photolithography and P-type ion implantation, wherein the floating island layer comprises a first doped region, a second doped region and a third doped region, and the second doped region is distributed in the first doped region, or a part of the second doped region is distributed in the first doped region, and a doping type of the first doped region is opposite to a doping type of the epitaxial layer, and a doping type of the second doped region is the same as the doping type of the epitaxial layer, and a doping type of the third doped region is the same as the doping type of the epitaxial layer;
repeatedly stacking the N-type epitaxial layers and the floating island layers to form a drift layer;
forming a surface layer and a bottom layer at two ends of the drift layer by metal sputtering or metal evaporation, and then implementing high temperature annealing to the surface layer and a bottom layer, so as to form an ohmic contact between the bottom layer and the N-type epitaxial layer, and forming a Schottky contact between the surface layer and the N-type epitaxial layer.
